(19) United States
(12) Patent Application Publication
(10) Pub. No.: US 2009/0035695 A1
(43) Pub. Date: Feb. 5, 2009

(54) POSITIVE WORKING LITHOGRAPHIC PRINTING PLATES

(75) Inventors: Paola Campestrini, Antwerpen (BE); Marc Van Damme, Bonheiden (BE); Stefaan Lingier, Assenede (BE)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: Agfa Graphics NV, Mortsel (BE)

(21) Appl. No.: 12/280,276

(22) PCT Filed: Feb. 9, 2007
(86) PCT No.: PCT/EP07/51276

§ 371 Date: Aug. 21, 2008

Related U.S. Application Data
(60) Provisional application No. 60/780,534, filed on Mar. 8, 2006.

(30) Foreign Application Priority Data
Feb. 28, 2006 (EP) 06110468.3

(51) Int. Cl. G03F 7/00; G03F 7/20

(52) U.S. Cl. 430/273.1; 430/270.1; 430/304

(57) ABSTRACT

A positive-working lithographic printing plate precursor is disclosed comprising on a grained and anodized aluminum support having a hydrophilic surface or which is provided with hydrophilic layer, a coating comprising:
(i) an infrared absorbing agent and at least one colorant;
(ii) a first layer comprising a heat-sensitive oleophilic resin; and
(iii) a second layer between said first layer and said hydrophilic support wherein said second layer comprises a polymer comprising at least one monomeric unit that comprises at least one sulfonamide group;
   wherein the surface of said grained and anodized aluminum support has a mean pit depth equal or smaller than 2.2 μm.

### FIELD OF THE INVENTION

The present invention relates to a heat-sensitive, positive-working lithographic printing plate precursor.

### BACKGROUND OF THE INVENTION

Lithographic printing presses use a so-called printing master such as a printing plate which is mounted on a cylinder of the printing press. The master carries a lithographic image on its surface and a print is obtained by applying ink to said image and then transferring the ink from the master onto a receiver material, which is typically paper. In conventional, so-called “wet” lithographic printing, ink as well as an aqueous fountain solution (also called dampening liquid) are supplied to the lithographic image which consists of oleophilic (or hydrophobic, i.e. ink-accepting, water-repelling) areas as well as hydrophilic (or oleophobic, i.e. water-accepting, ink-repelling) areas. In so-called driographic printing, the lithographic image consists of ink-accepting and ink-abhesive (ink-repelling) areas and during driographic printing, only ink is supplied to the master.

Printing masters are generally obtained by the image-wise exposure and processing of an imaging material called plate precursor. In addition to the well-known photosensitive, so-called pre-sensitized plates, which are suitable for UV contact exposure through a film mask, also heat-sensitive printing plate precursors have become very popular in the late 1990s. Such thermal materials offer the advantage of daylight stability and are especially used in the so-called computer-to-plate method wherein the plate precursor is directly exposed, i.e. without the use of a film mask. The material is exposed to heat or to infrared light and the generated heat triggers a (physico-)chemical process, such as ablation, polymerization, insolubilization by cross linking of a polymer, heat-induced solubilization, or by particle coagulation of a thermoplastic polymer latex.

The most popular thermal plates form an image by a heat-induced solubility difference in an alkaline developer between exposed and non-exposed areas of the coating. The coating typically comprises an oleophilic binder, e.g. a phenolic resin, of which the rate of dissolution in the developer is either reduced (negative working) or increased (positive working) by the image-wise exposure. During processing, the solubility differential leads to the removal of the non-image (non-printing) areas of the coating, thereby revealing the hydrophilic support, while the image (printing) areas of the coating remain on the support. Typical examples of such plates are described in e.g. EP-A 625728, 823327, 825927, 864420, 894622 and 901902. Negative working embodiments of such thermal materials often require a pre-heat step between exposure and development as described in e.g. EP-A 625,728.

For positive plate precursors that work according to the mechanism of a heat-induced solubility difference in an alkaline developer, a sufficient differentiation between the development kinetics of exposed and non-exposed areas is essential. The dissolution of the exposed coating in the developer should be completed before the unexposed coating also starts dissolving in the developer. If this differentiation is not large enough, low quality prints showing unsharp edges and toning (ink-acceptance in exposed areas) and a narrow development latitude may be obtained. In addition, while the printing areas (non-exposed areas) should remain essentially unaffected, the exposed areas should be completely and profoundly removed (i.e. clean-out) during the development step. However, especially for printing plates comprising a grained and anodized aluminum support, clean-out problems have been reported in the prior art.

U.S. Pat. No. 5,728,503 provides a grained and anodized aluminum support or a light sensitive printing plate having a substantially uniform topography comprising peaks and valleys and surface roughness parameters Ra (0.10-0.5 μm), Rt (0-6 μm), Rp (0-4 μm) and Rz (0-5 μm).

EP 1,400,351 discloses a lithographic printing plate precursor containing an aluminum support and a photosensitive layer containing an alkali-soluble resin and an infrared absorber, wherein the photosensitive layer has a coating weight of 0.5 to 3 g/m² and a thickness distribution with a maximum relative standard deviation of 20%.

WO 02/01291 discloses a lithographic plate comprising on a roughened substrate a substantially conformal radiation-sensitive layer; i.e. the surface of the radiation-sensitive layer has peaks and valleys substantially corresponding to the major peaks and valleys of the microscopic surface of the roughened substrate. Tackiness, block resistance and press durability of the plate are improved.

U.S. Pat. No. 6,912,956 discloses a printing plate material comprising a substrate having a center line average surface roughness Ra of 0.2 to 1.0 μm and an oil-retention volume A2 of 1 to 10, and provided thereon a component layer onto which an image is capable of being recorded by imagewise exposure with an infrared laser.

Despite the solutions provided in the prior art, developability problems for printing plates comprising supports having a roughened surface are still a major issue. Often, part of the coating fails to gain sufficient solubility in a developer and tends to remain on the support at non-image areas resulting in toning (ink acceptance at the non-image areas). These coating residues may be visible as coloured spots; the colour of these spots is most probably due to the presence of a colorant in the coating.

### SUMMARY OF THE INVENTION

It is an object of the present invention to provide a positive-working lithographic printing plate precursor that works according to the mechanism of a heat-induced solubility difference in an alkaline developer, and that comprises an alkali soluble coating on a grained and anodized aluminum support, which does not show the occurence of coating residues—visible as coloured spots at non-image areas—after exposure and development in an alkaline developer.

According to the present invention, the above object is realized by the subject-matter of claim 1; i.e. a positive-working lithographic printing plate precursor comprising on a grained and anodized aluminum support having a hydrophilic surface, a coating comprising:

(i) an infrared absorbing agent and at least one colorant;
(ii) a first layer comprising a heat-sensitive oleophilic resin;
(iii) and a second layer between said first layer and said hydrophilic support wherein said second layer comprises a polymer comprising at least one monomeric unit that comprises at least one sulfonamide group;
characterized in that the surface of said grained and anodized aluminum support has a mean pit depth equal or smaller than 2.2 μm.

It was found that the occurrence of colored coating residues at the non-image areas of the surface of a grained and anodized aluminum support characterized by a mean pit depth equal or smaller 2.2 μm, after exposure and development in an alkaline solution, is substantially reduced. A detailed study of the microstructure of the surface of a grained and anodized aluminum support, revealed that supports with a specific surface characterized by a mean pit depth equal or smaller 2.2 μm have an improved clean out behavior of a coating provided thereon, and more specific, the presence of colored spots after exposure and development is substantially reduced.

Preferred embodiments of the present invention are described in the dependent claims.

### BRIEF DESCRIPTION OF THE DRAWINGS

FIG. 1 shows a two-dimensional surface profile.

FIG. 2 shows a bearing ratio curve of a surface profile.

FIG. 3 shows the Rₖ-construction drawn on the bearing ratio curve.

FIG. 4 shows an interferometer image thresholded at height D defined in the Rₖ-construction, and wherein the gray-scale relates to the depth of the pits and their distribution throughout the cross-section.

FIG. 5 shows a graph illustrating the newly developed threshold procedure for determination of the pit size distribution.

### DETAILED DESCRIPTION OF THE INVENTION

The printing plate of the present invention comprises an electrochemically grained and anodized aluminum support. The support may be a sheet-like material such as a plate or it may be a cylindrical element such as a sleeve which can be slid around a print cylinder of a printing press.

The aluminium is preferably grained by electrochemical graining, and anodized by means of anodizing techniques employing sulphuric acid or a sulphuric acid/phosphoric acid mixture. Methods of both graining and anodization of aluminum are known in the art.

By graining (or roughening) the aluminium support, both the adhesion of the printing image and the wetting characteristics of the non-image areas are improved. By varying the type and/or concentration of the electrolyte and the applied voltage in the graining step, different type of grains can be obtained.

By anodising the aluminium support, its abrasion resistance and hydrophilic nature are improved. The microstructure as well as the thickness of the Al₂O₃ layer are determined by the anodising step, the anodic weight (g/m² Al₂O₃ formed on the aluminium surface) varies between 1 and 8 g/m².

The grained and anodized aluminum support may be post-treated to improve the hydrophilic properties of its surface. For example, the aluminum oxide surface may be silicated by treating its surface with a sodium silicate solution at elevated temperature, e.g. 95° C. Alternatively, a phosphate treatment may be applied which involves treating the aluminum oxide surface with a phosphate solution that may further contain an inorganic fluoride. Further, the aluminum oxide surface may be rinsed with an organic acid and/or salt thereof, e.g. carboxylic acids, hydrocarboxylic acids, sulphonic acids or phosphonic acids, or their salts, e.g. succinates, phosphates, phosphonates, sulphates, and sulphonates. A citric acid or citrate solution is preferred. This treatment may be carried out at room temperature or may be carried out at a slightly elevated temperature of about 30° C. to 50° C. A further interesting treatment involves rinsing the aluminum oxide surface with a bicarbonate solution. Still further, the aluminum oxide surface may be treated with polyvinylphosphonic acid, polyvinylmethylphosphonic acid, phosphoric acid esters of polyvinyl alcohol, polyvinylsulfonic acid, polyvinylbenzenesulfonic acid, sulfuric acid esters of polyvinyl alcohol, and acetals of polyvinyl alcohols formed by reaction with a sulfonated aliphatic aldehyde. It is further evident that one or more of these post treatments may be carried out alone or in combination. More detailed descriptions of these treatments are given in GB 1084070, DE 4423140, DE 4417907, EP 659909, EP 537633, DE 4001466, EP A 292801, EP A 291760 and U.S. Pat. No. 4,458,005.

According to the present invention, it was found that Ra values (arithmetical mean center-line roughness, see ISO 4287/1 or DIN 4762) of the lithographic support do not correlate with the occurrence of colored spots after exposure and development of the coating. It is believed that deep and/or large pits occurring on the surface of the lithographic support are responsible for formation of coloured spots. Ra measurements give average values of peaks and valleys present on the surface of a support and the presence of deep and/or large pits do therefore not substantially influence the Ra value. Consequently, Ra values do not correlate well with the occurrence of colored spots. According to the current invention, it was found that a lithographic printing plate precursor comprising a heat-sensitive coating on a roughened substrate characterized by a mean pit depth equal or less than 2.2 μm, provides a printing plate with a reduced amount of coloured spots compared to a printing plate precursor containing a roughened substrate with a mean pit depth which is greater than 2.2 μm. The mean pit depth is defined as follows.

First, three dimensional images are recorded of the substrate which characterize the graining morphology surface or the roughness properties of the surface of said substrate. From these images several parameters that describe various aspects of the surface-morphology can be calculated. The Bearing Ratio Analysis technique (see for example Wyko Surface Profilers Technical Reference Manual, September 1999, from Veeko, Metrology Group (pages 3-3 to 3-11) or US 2004/0103805), has been used for calculating these parameters. The three dimensional images or surface profiles can be obtained by using a white-light interferometer from Veeco (NT3300, commercially available from Veeco Metology Group, Arizona, USA).

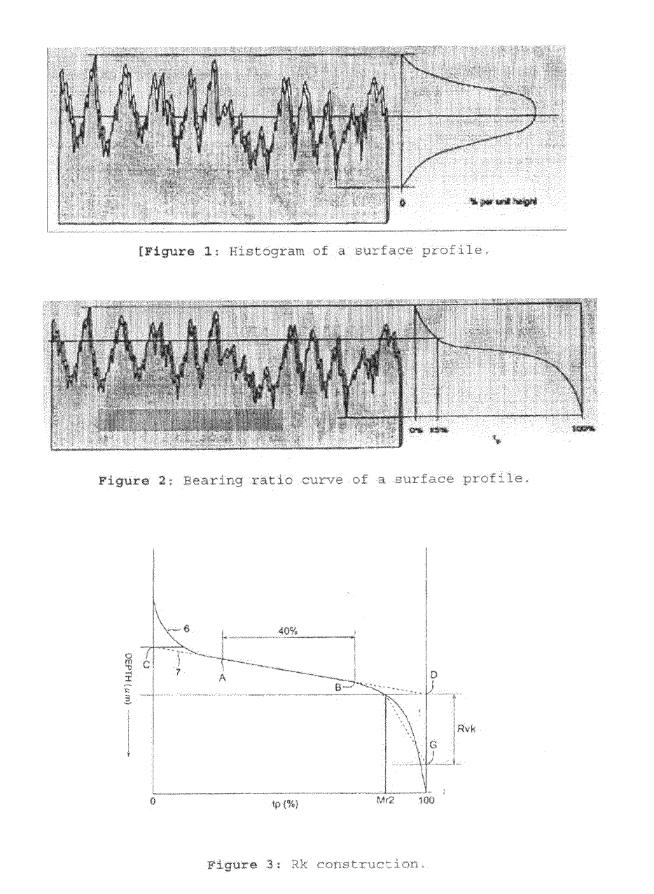

From the obtained surface profile, two curves can be derived: the histogram of the surface profile (FIG. 1) and the bearing ratio curve (FIG. 2). The histogram of the surface profile, also named Amplitude Distribution Function (ADF), gives the probability that the profile of the surface has a certain height z at any xy position. In other words, the ADF gives the probability that a point on the surface profile at a randomly selected position xy, has a height of approximately z. The bearing ratio curve is the mathematical integral of the ADF and each point on the bearing ratio curve has the physical significance of showing what fraction of a profile lies above a certain height. In other words, the bearing ratio curve shows the percentage of intercepted material by a plane parallel to the surface plane, versus the depth of that plane into the surface.

From the bearing ratio curve, parameters describing the surface morphology are defined using the so-called Rk-construction (FIG. 3). These parameters are core roughness depth (Rk), reduced peak height (Rpk), reduced valley depth (Rvk) and valley material component (100%-Mr2) and are defined as follows in the ISO standard 13565-1996:

Core roughness depth (Rₖ): is the vertical height between the left and right intercepts of the line through the ends of the minimum height 40% window.
Reduced peak height (Rₚₖ): is an estimate of the small peaks above the main plateau of the surface.
Reduced valley depth (Rᵥₖ): is an estimate of the depth of the valleys.
Peak material component (Mᵣ₁): is the fraction of the surface that consists of small peaks.
Valley material component (100%-Mᵣ₂): is the fraction of the surface that consists of deeper valleys.

The heights C and D at the surface profile are determined in the Rk-construction by identifying the minimum secant slope. The minimum secant slope is obtained by sliding a 40% window (of the 0 to 100% axis in FIG. 3) across the bearing ratio curve. This window intersects the curve at two points, i.e. points A and B and the goal is to find the position where the slope between the two points is minimised. When the minimum slope is found, a line through points A and B is drawn and the intercepts on the ordinates at bearing ratio 0% and 100% yield respectively points C and D.

According to the present invention, a new threshold procedure based on the parameters defined in the Rₖ construction has been defined which enables to evaluate the pit size distribution.

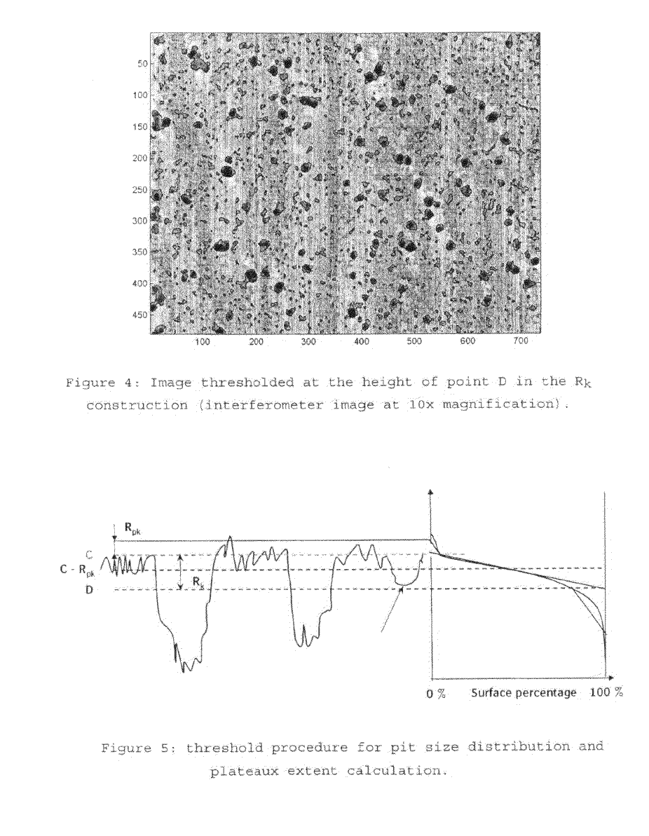

For the evaluation of the pit size distribution, first of all the three dimensional interferometer image is thresholded at height D (FIG. 4). FIG. 4 is in fact a cross-section at height D of the aluminium surface and shows the pits at this height. The gray-scale of FIG. 4 relates to the depth of the pits and their distribution throughout the cross-section. Each pixel has a depth value that enables to create the grey-scale image. The threshold enables to identify aid separate objects, i.e. pits. The pits are separated from each other using a convex-components analysis. The area, depth, and volume of each single pit can then be calculated using appropriate software such as MatLab. For example, the area of a pit is calculated on the thresholded image by multiplying the number of pixels belonging to a pit with the physical area of one pixel. From these values the mean and standard deviation of the pit area, depth and volume at the threshold height can be calculated. The pit depth obtained from this threshold procedure is corrected to the real depth by adding Rk (FIG. 5). Similarly, the volume of the pit is also corrected by adding the volume of a cylinder having as area the calculated area of the pit (at level D) and as height Rk (FIG. 5). The pits with a depth lower than Rk+Rpk (indicated by the arrow in FIG. 5) are not identified as pits by this image analysis. However, this threshold procedure enables to compare the size distribution of the deep pits of different substrates.

It was found that the results of pit depth, area and volume obtained via the above described procedure, correlate well with the number of coloured spots retained on the substrate after exposure and development:
(i) above a mean pit depth of 2.2 μm, the amount of coloured spots increases. The mean pit depth of the hydrophilic surface of the grained and anodized aluminum support used in the material of the present invention is lower than 2.2 μm, preferably lower than 2.0 μm and even more preferably lower than 1.8 μm.
(ii) above a mean pit area of 25 μm², the amount of coloured spots increases. The mean pit area of the hydrophilic surface of the grained and anodized aluminum support used in the material of the present invention is lower than 25 μm², preferably lower than 22 μm² and even more preferably lower than 20 μm².
(iii) above a mean pit volume area of 55 μm³, the amount of coloured spots increases. The mean pit volume of the hydrophilic surface of the grained and anodized aluminum support used in the material of the present invention is lower than 55 μm³, preferably lower than 45 μm³ and even more preferably lower than 40 μm³.

The coating of the present invention comprises at least two layers; the layers are designated hereinafter as first and second layer, the second layer being closest to the support, i.e. located between the support and the first layer.

The printing plate precursor is positive-working, i.e. after exposure by heat and/or light and development, the exposed areas of the coating are removed from the support and define hydrophilic (non-printing) areas, whereas the unexposed coating is not removed from the support and defines the printing areas.

The first layer of the coating comprises an oleophilic resin. The oleophilic resin is preferably a polymer that is soluble in an aqueous developer, more preferably an aqueous alkaline developing solution with a pH between 7.5 and 14. Preferred polymers are phenolic resins e.g. novolac, resoles, polyvinyl phenols and carboxy substituted polymers. Typical examples of these polymers are described in DE-A-4007428, DE-A-4027301 and DE-A-4445820. The amount of phenolic resin present in the first layer is preferably at least 50% by weight, preferably at least 80% by weight relative to the total weight of all the components present in the first layer.

In a preferred embodiment, the oleophilic resin is preferably a phenolic resin wherein the phenyl group or the hydroxy group is chemically modified with an organic substituent. The phenolic resins which are chemically modified with an organic substituent may exhibit an increased chemical resistance against printing chemicals such as fountain solutions or press chemicals such as plate cleaners. Examples of such chemically modified phenolic resins are described in EP-A 0 934 822, EP-A 1 072 432, U.S. Pat. No. 5,641,608, EP-A 0 982 123, WO 99/01795, EP-A 02 102 446, EP-A 02 102 444, EP-A 02 102 445, EP-A 02 102 443, EP-A 03 102 522. The modified resins described in EP-A 02 102-446, are preferred, especially those resins wherein the phenyl-group of said phenolic resin is substituted with a group having the structure —N═N-Q, wherein the —N═N— group is covalently bound to a carbon atom of the phenyl group and wherein Q is an aromatic group.

The second layer located between the first layer and the hydrophilic support of the printing plate precursor of the present invention, comprises a polymer or copolymer (i.e. (co)polymer) comprising at least one monomeric unit that comprises at least one sulfonamide group. Hereinafter, ‘a (co)polymer comprising at least one monomeric unit that comprises at least one sulfonamide group’ is also referred to as “a sulphonamide (co)polymer”. The sulphonamide (co)polymer is preferably alkali soluble. The sulphonamide group is preferably represented by —NR—SO₂—, —SO₂—NR— or —SO₂—NRR′ wherein R and R′ each independently represent hydrogen or an organic substituent.

Sulphonamide (co)polymers are preferably high molecular weight compounds prepared by homopolymerization of monomeric units containing at least one sulphonamide group or by copolymerization of such monomeric units and other polymerizable monomeric units.

Examples of monomeric units containing at least one sulphonamide group include monomeric units further containing at least one polymerizable unsaturated bond such as an acryloyl, allyl or vinyloxy group. Suitable examples are disclosed in U.S. Pat. No. 5,141,838, EP 1545878, EP 909,657, EP 0 894 622 and EP 1,120,246.

Examples of monomeric units copolymerized with the monomeric units containing at least one sulphonamide group include monomeric units as disclosed in EP 1,262,318, EP 1,275,498, EP 909,657, EP 1,120,246, EP 0 894 622 and EP 1,400,351.

Suitable examples of sulphonamide (co)polymers and/or their method of preparation are disclosed in EP-A 933 682, EP-A 982 123, EP-A 1 072 432, WO 99/63407 and EP-A 1,604,818.

A highly preferred example of a sulphonamide (co)polymer is a homopolymer or copolymer comprising a structural unit represented by the following general formula (I):

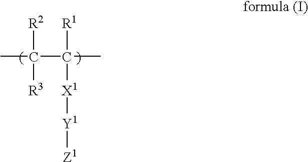

wherein:
R¹ represents hydrogen or a hydrocarbon group having up to 12 carbon atoms; preferably R¹ represents hydrogen or a methyl group;
R² and R³ independently represent hydrogen or a hydrocarbon group; preferably R² and R³ represent hydrogen;
X¹ represents a single bond or a divalent linking group. The divalent linking group may have up to 20 carbon atoms and may contain at least one atom selected from C, H, N, O and S.
Preferred divalent linking groups are a linear alkylene group having 1 to 18 carbon atoms, a linear, branched, or cyclic group having 3 to 18 carbon atoms, an alkynylene group having 2 to 18 carbon atoms and an arylene group having 6 to 20 atoms, —O—, —S—, —CO—, —CO—O—, —O—CO—, —CS—, —NR^{h}Rⁱ—, —CO—NR^{h}—, —NR^{h}—CO—, —NR^{h}—CO—O—, —O—CO—NR^{h}—, —NR^{h}—CO—NRⁱ—, —NR^{h}—CS—NRⁱ—, a phenylene group, a naphtalene group, an anthracene group, a heterocyclic group, or combinations thereof, wherein R^{h} and Rⁱ each independently represent hydrogen or an optionally substituted alkyl, alkenyl, alkynyl, cycloalkyl, heterocyclic, aryl, heteroaryl, aralkyl or heteroaralkyl group. Preferred substituents on the latter groups are an alkoxy group having up to 12 carbon atoms, a halogen or a hydroxyl group. Preferably X¹ is a methylene group, an ethylene group, a propylene group, a butylene group, an isopropylene group, cyclohexylene group, a phenylene group, a tolylene group or a biphenylene group;
Y¹ is a bivalent sulphonamide group represented by —NR^{j}—SO₂— or —SO₂—NR^{k}— wherein R^{j} and R^{k} each independently represent hydrogen, an optionally substituted alkyl, alkanoyl, alkenyl, alkynyl, cycloalkyl, heterocyclic, aryl, heteroaryl, aralkyl or heteroaralkyl group or a group of the formula —C(═N)—NH—R², wherein R² represents hydrogen or an optionally substituted alkyl or aryl group;
Z¹ represents a bi-, tri- or quadrivalent linking group or a terminal group. When Z¹ is a bi-, tri- or quadrivalent linking group, the remaining 1 to 3 bonds of Z¹ are linked to Y¹ forming crosslinked structural units.
When Z¹ is a terminal group, it is preferably represented by hydrogen or an optionally substituted linear, branched, or cyclic alkylene or alkyl group having 1 to 18 carbon atoms such as a methyl group, an ethyl group, a propyl group, an isopropyl group, a butyl group, an isobutyl group, a t-butyl group, a sec-butyl group, a pentyl group, a hexyl group, a cyclopentyl group, a cyclohexyl group, an octyl group, an optionally substituted arylene or aryl group having 6 to 20 carbon atoms; an optionally substituted hetero-arylene or heteroaryl group; a linear, branched, or cyclic alkenylene or alkenyl group having 2 to 18 carbon atoms, a linear, branched, or cyclic alkynylene or alkynyl group having 2 to 18 carbon atom or an alkoxy group.
When Z is a bi, tri- or quadrivalent linking group, it is preferably represented by an above mentioned terminal group of which hydrogen atoms in numbers corresponding to the valence are eliminated therefrom.
Examples of preferred substituents optionally present on the groups representing Z¹ are an alkyl group having up to 12 carbon atoms, an alkoxy group having up to 12 carbon atoms, a halogen atom or a hydroxyl group.

The structural unit represented by the general formula (I) has preferably the following groups:

X¹ represents an alkylene, cyclohexylene, phenylene or tolylene group, —O—, —S—, —CO—, —CO—O—, —O—CO—, —CS—, —NR^{h}Rⁱ—, —CO—NR^{h}—, —NR^{h}—CO—, —NR^{h}—CO—O—, —O—CO—NR^{h}—, —NR^{h}—CO—NRⁱ—, —NR^{h}—CS—NRⁱ—, or combinations thereof, and wherein R^{h} and Rⁱ each independently represent hydrogen or an optionally substituted alkyl, alkenyl, alkynyl, cycloalkyl, heterocyclic, aryl, heteroaryl, aralkyl or heteroaralkyl group. Preferred substituents on the latter groups are an alkoxy group having up to 12 carbon atoms, a halogen or a hydroxyl group;
Y¹ is a bivalent sulphonamide group represented by
—NR^{j}—SO₂—, —SO₂—NR^{k}— wherein R^{j} and R^{k} each independently represent hydrogen, an optionally substituted alkyl, alkanoyl, alkenyl, alkynyl, cycloalkyl, heterocyclic, aryl, heteroaryl, aralkyl or heteroaralkyl group;
Z¹ is a terminal group represented by hydrogen, an alkyl group such as a methyl group, an ethyl group, a propyl group, an isopropyl group, a butyl group, an isobutyl group, a t-butyl group, a sec-butyl group, a pentyl group, a hexyl group, a cyclopentyl group, a cyclohexyl group or an octyl group, a benzyl group, an optionally substituted aryl or heteroaryl group, a naphtyl group, an anthracenyl group, a pyridyl group, an allyl group or a vinyl group.

Specific preferred examples of sulphonamide (co)polymers are polymers comprising N-(p-aminosulfonylphenyl) (meth)acrylamide, N-(m-aminosulfonylphenyl) (meth)acrylamide and/or N-(o-aminosulfonylphenyl) (meth)acrylamide. A particularly preferred sulphonamide (co)polymer is a polymer comprising N-(p-aminosulphonylphenyl)methacrylamide wherein the sulphonamide group comprises an optionally substituted straight, branched, cyclic or heterocyclic alkyl group, an optionally substituted aryl group or an optionally substituted heteroaryl group.

The second layer may further comprise additional hydrophobic binders such as a phenolic resin (e.g. novolac, resoles or polyvinyl phenols), a chemically modified phenolic resin or a polymer containing a carboxyl group, a nitrile group or a maleimide group.

The dissolution behavior of the coating in the developer can be fine-tuned by optional solubility regulating components. More particularly, development accelerators and development inhibitors can be used. These ingredients can be added to the first layer, to the second layer and/or to an optional other layer of the coating.

Development accelerators are compounds which act as dissolution promoters because they are capable of increasing the dissolution rate of the coating. For example, cyclic acid anhydrides, phenols or organic acids can be used in order to improve the aqueous developability. Examples of the cyclic acid anhydride include phthalic anhydride, tetrahydrophthalic anhydride, hexahydrophthalic anhydride, 3,6-endoxy-4-tetrahydro-phthalic anhydride, tetrachlorophthalic anhydride, maleic anhydride, chloromaleic anhydride, alpha-phenylmaleic anhydride, succinic anhydride, and pyromellitic anhydride, as described in U.S. Pat. No. 4,115,128. Examples of the phenols include bisphenol A, p-nitrophenol, p-ethoxyphenol, 2,4,4′-trihydroxybenzophenone, 2,3,4-trihydroxy-benzophenone, 4-hydroxybenzophenone, 4,4′,4″-trihydroxy-triphenylmethane, and 4,4′,3″, 4″-tetrahydroxy-3,5,3′,5′-tetramethyltriphenyl-methane, and the like. Examples of the organic acids include sulfonic acids, sulfinic acids, alkylsulfuric acids, phosphonic acids, phosphates, and carboxylic acids, as described in, for example, JP-A Nos. 60-88,942 and 2-96,755. Specific examples of these organic acids include p-toluenesulfonic acid, dodecylbenzenesulfonic acid, p-toluenesulfinic acid, ethylsulfuric acid, phenylphosphonic acid, phenylphosphinic acid, phenyl phosphate, diphenyl phosphate, benzoic acid, isophthalic acid, adipic acid, p-toluic acid, 3,4-dimethoxybenzoic acid, 3,4,5-trimethoxybenzoic acid, 3,4,5-trimethoxycinnamic acid, phthalic acid, terephthalic acid, 4-cyclohexene-1,2-dicarboxylic acid, erucic acid, lauric acid, n-undecanoic acid, and ascorbic acid. The amount of the cyclic acid anhydride, phenol, or organic acid contained in the coating is preferably in the range of 0.05 to 20% by weight, relative to the coating as a whole. Polymeric development accelerators such as phenolic-formaldehyde resins comprising at least 70 mol % meta-cresol as recurring monomeric units are also suitable development accelerators.

In a preferred embodiment, the coating also contains developer resistance means, also called development inhibitors, i.e. one or more ingredients which are capable of delaying the dissolution of the unexposed areas during processing. The dissolution inhibiting effect is preferably reversed by heating, so that the dissolution of the exposed areas is not substantially delayed and a large dissolution differential between exposed and unexposed areas can thereby be obtained. The compounds described in e.g. EP-A 823 327 and WO97/39894 are believed to act as dissolution inhibitors due to interaction, e.g. by hydrogen bridge formation, with the alkali-soluble resin(s) in the coating. Inhibitors of this type typically comprise at least one hydrogen bridge forming group such as nitrogen atoms, onium groups, carbonyl (—CO—), sulfinyl (—SO—) or sulfonyl (—SO₂—) groups and a large hydrophobic moiety such as one or more aromatic rings. Some of the compounds mentioned below, e.g. infrared dyes such as cyanines and contrast dyes such as quaternized triarylmethane dyes can also act as a dissolution inhibitor.

Other suitable inhibitors improve the developer resistance because they delay the penetration of the aqueous alkaline developer into the coating. Such compounds can be present in the first and/or second layer as described in e.g. EP-A 950 518, and/or in a development barrier layer on top of said layer, as described in e.g. EP-A 864 420, EP-A950 517, WO 99/21725 and WO 01/45958. In the latter embodiment, the solubility of the barrier layer in the developer or the penetrability of the barrier layer by the developer can be increased by exposure to heat or infrared light.

Preferred examples of inhibitors which delay the penetration of the aqueous alkaline developer into the coating include the following:
(a) A polymeric material which is insoluble in or impenetrable by the developer, e.g. a hydrophobic or water-repellent polymer or copolymer such as acrylic polymers, polystyrene, styrene-acrylic copolymers, polyesters, polyamides, polyureas, polyurethanes, nitrocellulosics and epoxy resins; or polymers comprising siloxane (silicones) and/or perfluoroalkyl units.
(b) Bifunctional compounds such as surfactants comprising a polar group and a hydrophobic group such as a long chain hydrocarbon group, a poly- or oligosiloxane and/or a perfluorinated hydrocarbon group. A typical example is Megafac F-177, a perfluorinated surfactant available from Dainippon Ink & Chemicals, Inc. A suitable amount of such compounds is between 10 and 100 mg/m², more preferably between 50 and 90 mg/m².
(c) Bifunctional block-copolymers comprising a polar block such as a poly- or oligo(alkylene oxide) and a hydrophobic block such as a long chain hydrocarbon group, a poly- or oligosiloxane and/or a perfluorinated hydrocarbon group. A suitable amount of such compounds is between 0.5 and 25 mg/m², preferably between 0.5 and 15 mg/m² and most preferably between 0.5 and 10 mg/m². A suitable copolymer comprises about 15 to 25 siloxane units and 50 to 70 alkyleneoxide groups. Preferred examples include copolymers comprising phenylmethylsiloxane and/or dimethylsiloxane as well as ethylene oxide and/or propylene oxide, such as Tego Glide 410, Tego Wet 265, Tego Protect 5001 or Silikophen P50/X, all commercially available from Tego Chemie, Essen, Germany. Said poly- or oligosiloxane may be a linear, cyclic or complex cross-linked polymer or copolymer. The term polysiloxane compound shall include any compound which contains more than one siloxane group —Si(R,R′)—O—, wherein R and R′ are optionally substituted alkyl or aryl groups. Preferred siloxanes are phenylalkylsiloxanes and dialkylsiloxanes. The number of siloxane groups in the polymer or oligomer is at least 2, preferably at least 10, more preferably at least 20. It may be less than 100, preferably less than 60.

It is believed that during coating and drying, the above mentioned inhibitor of type (b) and (c) tends to position itself, due to its bifunctional structure, at the interface between the coating and air and thereby forms a separate top layer even when applied as an ingredient of the coating solution of the first and/or second layer. Simultaneously, the surfactants also act as a spreading agent which improves the coating quality. The separate top layer thus formed seems to be capable of acting as the above mentioned barrier layer which delays the penetration of the developer into the coating.

Alternatively, the inhibitor of type (a) to (c) can be applied in a separate solution, coated on top of the first, second and optional other layers of the coating. In that embodiment, it may be advantageous to use a solvent in the separate solution that is not capable of dissolving the ingredients present in the other layers so that a highly concentrated water-repellent or hydrophobic phase is obtained at the top of the coating which is capable of acting as the above mentioned development barrier layer.

In addition, the first or second layer of the coating or an optional other layer may comprise polymers that further improve the run length and/or the chemical resistance of the plate. Examples thereof are polymers comprising imido (—CO—NR—CO—) pendant groups, wherein R is hydrogen, optionally substituted alkyl or optionally substituted aryl, such as the polymers described in EP-A 894 622, EP-A 901 902, EP-A 933 682 and WO 99/63407.

The coating also contains an infrared light absorbing dye or pigment which may be present in the first layer, and/or in the second layer, and/or in the optional barrier layer discussed above and/or in an optional other layer. Preferred IR absorbing dyes are cyanine dyes, merocyanine dyes, indoaniline dyes, oxonol dyes, pyrilium dyes and squarilium dyes. Examples of suitable IR dyes are described in e.g. EP-As 823327, 978376, 1029667, 1053868, 1093934; WO 97/39894 and 00/29214. A preferred compound is the following cyanine dye:

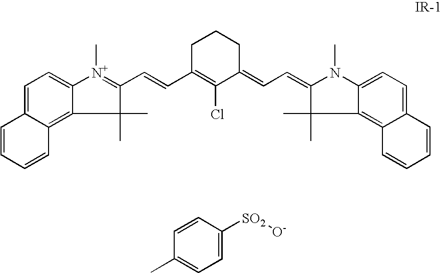

The concentration of the IR-dye in the coating is preferably between 0.25 and 15.0% wt, more preferably between 0.5 and 10.0% wt, most preferably between 1.0 and 7.5% wt relative to the coating as a whole.

The coating of the present invention comprises one or more colorant(s) such as dyes or pigments which provide a visible color to the coating and which remain in the coating at unexposed areas so that a visible image is obtained after exposure and processing. Such dyes are often called contrast dyes or indicator dyes. Preferably, the dye has a blue color and an absorption maximum in the wavelength range between 600 nm and 750 nm. Although the dye absorbs visible light, it preferably does not sensitize the printing plate precursor, i.e. the coating does not become more soluble in the developer upon exposure to visible light. Typical examples of such contrast dyes are the amino-substituted tri- or diarylmethane dyes, e.g. crystal violet, methyl violet, victoria pure blue, flexoblau 630, basonylblau 640, auramine and malachite green. Also the dyes which are discussed in depth in EP-A 400,706 are suitable contrast dyes. The contrast dye(s) may be present in the first layer, and/or the second layer, and/or in any layer discussed above, and/or in an optional other layer.

To protect the surface of the coating, in particular from mechanical damage, a protective layer may also optionally be applied. The protective layer generally comprises at least one water-soluble binder, such as polyvinyl alcohol, polyvinylpyrrolidone, partially hydrolyzed polyvinyl acetates, gelatin, carbohydrates or hydroxyethylcellulose, and can be produced in any known manner such as from an aqueous solution or dispersion which may, if required, contain small amounts—i.e. less than 5% by weight based on the total weight of the coating solvents for the protective layer—of organic solvents. The thickness of the protective layer can suitably be any amount, advantageously up to 5.0 μm, preferably from 0.1 to 3.0 μm, particularly preferably from 0.15 to 1.0 μm.

Optionally, the coating may further contain additional ingredients such as surfactants, especially perfluoro surfactants, silicon or titanium dioxide particles or polymers particles such as matting agents and spacers.

For the preparation of the lithographic plate precursor, any known method can be used. For example, the above ingredients can be dissolved in a solvent mixture which does not react irreversibly with the ingredients and which is preferably tailored to the intended coating method, the layer thickness, the composition of the layer and the drying conditions. Suitable solvents include ketones, such as methyl ethyl ketone (butanone), as well as chlorinated hydrocarbons, such as trichloroethylene or 1,1,1-trichloroethane, alcohols, such as methanol, ethanol or propanol, ethers, such as tetrahydrofuran, glycol-monoalkyl ethers, such as ethylene glycol monoalkyl ether, e.g. 2-methoxy-1-propanol, or propylene glycol monoalkyl ether and esters, such as butyl acetate or propylene glycol monoalkyl ether acetate. It is also possible to use a solvent mixture which, for special purposes, may additionally contain solvents such as acetonitrile, dioxane, dimethylacetamide, dimethylsulfoxide or water.

Any coating method can be used for applying two or more coating solutions to the hydrophilic surface of the support. The multi-layer coating can be applied by coating/drying each layer consecutively or by the simultaneous coating of several coating solutions at once. In the drying step, the volatile solvents are removed from the coating until the coating is self-supporting and dry to the touch. However it is not necessary (and may not even be possible) to remove all the solvent in the drying step. Indeed the residual solvent content may be regarded as an additional composition variable by means of which the composition may be optimised. Drying is typically carried out by blowing hot air onto the coating, typically at a temperature of at least 70° C., suitably 80-150° C. and especially 90-140° C. Also infrared lamps can be used. The drying time may typically be 15-600 seconds.

Between coating and drying, or after the drying step, a heat treatment and subsequent cooling may provide additional benefits, as described in WO99/21715, EP-A 1074386, EP-A 1074889, WO/0029214, WO/04030923, WO/04030924, WO/04030925.

The plate precursor can be image-wise exposed directly with heat, e.g. by means of a thermal head, or indirectly by infrared light, preferably near infrared light. The infrared light is preferably converted into heat by an IR light absorbing compound as discussed above. The heat-sensitive lithographic printing plate precursor is preferably not sensitive to visible light, i.e. no substantial effect on the dissolution rate of the coating in the developer is induced by exposure to visible light. Most preferably, the coating is not sensitive to ambient daylight, i.e. visible (400-750 nm) and near UV light (300-400 nm) at an intensity and exposure time corresponding to normal working conditions so that the plate precursor can be handled without the need for a safe light environment. “Not sensitive” to daylight shall mean that no substantial change of the dissolution rate of the coating in the developer is induced by exposure to ambient daylight. In a preferred daylight stable embodiment, the coating does not comprise photosensitive ingredients, such as (quinone)diazide or diazo(nium) compounds, photoacids, photoinitiators, sensitizers etc., which absorb the near UV and/or visible light that is present in sun light or office lighting and thereby change the solubility of the coating in exposed areas.

The printing plate precursor can be exposed to infrared light by means of e.g. LEDs or a laser. Most preferably, the light used for the exposure is a laser emitting near infrared light having a wavelength in the range from about 750 to about 1500 nm, more preferably 750 to 1100 nm, such as a semiconductor laser diode, a Nd:YAG or a Nd:YLF laser. The required laser power depends on the sensitivity of the plate precursor, the pixel dwell time of the laser beam, which is determined by the spot diameter (typical value of modern plate-setters at 1/e² of maximum intensity: 5-25 μm), the scan speed and the resolution of the exposure apparatus (i.e. the number of addressable pixels per unit of linear distance, often expressed in dots per inch or dpi; typical value: 1000-4000 dpi).

Two types of laser-exposure apparatuses are commonly used: internal (ITD) and external drum (XTD) platesetters. ITD plate-setters for thermal plates are typically characterized by a very high scan speed up to 500 m/sec and may require a laser power of several Watts. XTD plate-setters for thermal plates having a typical laser power from about 200 mW to about 1 W operate at a lower scan speed, e.g. from 0.1 to 10 m/sec. An XTD platesetter equipped with one or more laserdiodes emitting in the wavelength range between 750 and 850 nm is an especially preferred embodiment for the method of the present invention.

The known plate-setters can be used as an off-press exposure apparatus, which offers the benefit of reduced press down-time. XTD plate-setter configurations can also be used for on-press exposure, offering the benefit of immediate registration in a multi-color press. More technical details of on-press exposure apparatuses are described in e.g. U.S. Pat. No. 5,174,205 and U.S. Pat. No. 5,163,368.

The formation of the lithographic image by the plate precursor is due to a heat-induced solubility differential of the coating during processing in the developer. The solubility differentiation between image (printing, oleophilic) and non-image (non-printing, hydrophilic) areas of the lithographic image is believed to be a kinetic rather than a thermodynamic effect, i.e. the non-image areas are characterized by a faster dissolution in the developer than the image-areas. As a result of said dissolution, the underlying hydrophilic surface of the support is revealed at the non-image areas. In a most preferred embodiment, the non-image areas of the coating dissolve completely in the developer before the image areas are attacked so that the latter are characterized by sharp edges and high ink-acceptance. The time difference between completion of the dissolution of the non-image areas and the onset of the dissolution of the image areas is preferably longer than 10 seconds, more preferably longer than 20 seconds and most preferably longer than 60 seconds, thereby offering a wide development latitude.

In the processing step, the non-image areas of the coating are removed by immersion in a conventional aqueous alkaline developer, which may be combined with mechanical rubbing, e.g. by a rotating brush. During development, any water-soluble protective layer present is also removed. Silicate-based developers which have a ratio of silicon dioxide to alkali metal oxide of at least 1 are preferred to ensure that the alumina layer (if present) of the substrate is not damaged. Preferred alkali metal oxides include Na₂O and K₂O, and mixtures thereof. In addition to alkali metal silicates, the developer may optionally contain further components, such as buffer substances, complexing agents, antifoams, organic solvents in small amounts, corrosion inhibitors, dyes, surfactants and/or hydrotropic agents as well known in the art. The developer may further contain compounds which increase the developer resistance of the non-image areas, e.g. a polyalcohol such as sorbitol, preferably in a concentration of at least 40 g/l, and/or a poly(alkylene oxide) containing compound such as e.g. Supronic B25, commercially available from RODIA, preferably in a concentration of at most 0.15 g/l.

The development is preferably carried out at temperatures of from 20 to 40° C. in automated processing units as customary in the art. For regeneration, alkali metal silicate solutions having alkali metal contents of from 0.6 to 2.0 mol/l can suitably be used. These solutions may have the same silica/alkali metal oxide ratio as the developer (generally, however, it is lower) and likewise optionally contain further additives. The required amounts of regenerated material must be tailored to the developing apparatuses used, daily plate throughputs, image areas, etc. and are in general from 1 to 50 ml per square meter of plate precursor. The addition can be regulated, for example, by measuring the conductivity as described in EP-A 0 556 690. The processing of the plate precursor may also comprise a rinsing step, a drying step and/or a gumming step. The plate precursor can, if required, be post-treated with a suitable correcting agent or preservative as known in the art. To increase the resistance of the finished printing plate and hence to extend the run length, the layer can be briefly heated to elevated temperatures (“baking”).

The printing plate thus obtained can be used for conventional, so-called wet offset printing, in which ink and an aqueous dampening liquid is supplied to the plate. Another suitable printing method uses so-called single-fluid ink without a dampening liquid. Suitable single-fluid inks have been described in U.S. Pat. No. 4,045,232; U.S. Pat. No. 4,981,517 and U.S. Pat. No. 6,140,392. In a most preferred embodiment, the single-fluid ink comprises an ink phase, also called the hydrophobic or oleophilic phase, and a polyol phase as described in WO 00/32705.

The oleophilic coating described herein can also be used as a thermo-resist for forming a pattern on a substrate by direct imaging techniques, e.g. in a PCB (printed circuit board) application as described in US 2003/0003406 A1.

### EXAMPLES

### 1) Preparation of the Lithographic Substrates

The lithographic substrates 1-20 used in the present invention are given in Table 1 and their preparation methods are given below.

TABLE 1
lithographic substrates 1-20.

| | | | | | Acetic | | Charge |
|---|---|---|---|---|---|---|---|
| Sub- | Mechanical | HCl | HNO₃ | SO₄²⁻ | acid | Al³⁺ | density |
| strate | graining | g/l | g/l | g/l | g/l | g/l | C/dm² |
| 1 | No | 9 | — | — | 15 | 5 | 1150 |
| 2 | No | 9 | — | — | 15 | 5 | 1050 |
| 3 | No | 9 | — | — | 15 | 5 | 1100 |
| 4 | No | 9 | — | — | 15 | 5 | 1250 |
| 5 | Yes | 12.5 | — | 12 | — | 5 | 900 |
| 6 | Yes | 12.5 | — | 12 | — | 5 | 800 |
| 7 | Yes | 12.5 | — | 12 | — | 5 | 960 |
| 8 | No | — | 15.4 | — | — | 5 | 1120 |
| 9 | No | 5 | — | 5 | — | 5 | 800 |
| 10 | No | 15 | — | 15 | — | 5 | 650 |
| 11 | No | 15 | — | 15 | — | 5 | 700 |
| 12 | No | 7.5 | — | — | 10 | 5 | 700 |
| 13 | No | 6.5 | — | — | 16 | 5 | 700 |
| 14 | No | 15 | — | 15 | — | 5 | 900 |
| 15 | No | 15 | — | 15 | — | 5 | 800 |
| 16 | No | 15 | — | 15 | — | 5 | 620 |
| 17 | No | 15 | — | 15 | — | 1.5 | 900 |
| 18 | No | 15 | — | 15 | — | 1.5 | 900 |
| 19 | No | 15 | — | 15 | — | 5 | 750 |
| 20 | No | 15 | — | 15 | — | 5 | 680 |

Substrate 1.

A 0.3 mm thick aluminium foil was degreased by dipping an aqueous solution containing 10 g/l NaOH at 47.5° C. for 20 seconds and rinsed for 20 seconds with a mixture of HCl and demineralised water. The foil was then electrochemically grained during 20 seconds using an alternating current in an aqueous solution containing 9 g/l HCl, 15 g/l acetic acid and 1.5 g/l Al³⁺ ions at a temperature of 29° C. and a charge density of about 1150 C/dm². The foil was then sprayed with water for 20 seconds. Afterwards, the aluminium foil was desmutted by etching with an aqueous solution containing 100 g/l of phosphoric acid at 45° C. for 20 seconds and rinsed with demineralised water. The foil was subsequently subjected to anodic oxidation in an aqueous solution containing 145 g/l of sulphuric acid at a temperature of 45° C. and a charge density of 500 C/dm², then washed with demineralised water. Afterwards, the foil was post-treated by dipping for 6 seconds in a solution containing 2.2 g/l PVPA at 70° C., then washed with demineralised water. The support thus obtained was characterised by a surface roughness Rₐ of 0.93 μm (measured with interferometer NT3300) and had an anodic weight of 6.6 g/m².

Substrate 2.

A 0.3 mm thick aluminium foil was degreased by dipping an aqueous solution containing 10 g/l NaOH at 47.5° C. for 20 seconds and rinsed for 20 seconds with a mixture of HCl and demineralised water. The foil was then electrochemically grained during 20 seconds using an alternating current in an aqueous solution containing 9 g/l HCl, 15 g/l acetic acid and 1.5 g/l Al³⁺ ions at a temperature of 29° C. and a charge density of about 1050 C/dm². The foil was then sprayed with water for 20 seconds. Afterwards, the aluminium foil was desmutted by etching with an aqueous solution containing 100 g/l of phosphoric acid at 45° C. for 20 seconds and rinsed with demineralised water. The foil was subsequently subjected to anodic oxidation in an aqueous solution containing 145 g/l of sulphuric acid at a temperature of 45° C. and a charge density of 200 C/dm², then washed with demineralised water. Afterwards, the foil was post-treated by dipping for 20 seconds in a solution containing 4.5 g/l K₂ZrF₆ at 46° C., then washed with demineralised water. The support thus obtained was characterised by a surface roughness Rₐ of 0.77 μm (measured with interferometer NT3300) and had an anodic weight of 3.2 g/m².

Substrate 3.

A 0.3 mm thick aluminium foil was degreased by dipping an aqueous solution containing 10 g/l NaOH at 47.5° C. for 20 seconds and rinsed for 20 seconds with a mixture of HCl and demineralised water. The foil was then electrochemically grained during 20 seconds using an alternating current in an aqueous solution containing 9 g/l HCl, 15 g/l acetic acid and 1.5 g/l Al³⁺ ions at a temperature of 29° C. and a charge density of 1100 C/dm². The foil was then sprayed with water for 20 seconds. Afterwards, the aluminium foil was desmutted by etching with an aqueous solution containing 100 g/l of phosphoric acid at 45° C. for 20 seconds and rinsed with demineralised water. The foil was subsequently subjected to anodic oxidation in an aqueous solution containing 145 g/l of sulphuric acid at a temperature of 45° C. and a charge density of about 200 C/dm², then washed with demineralised water. Afterwards, the foil was post-treated by dipping for 20 seconds in a solution containing 4.5 g/l K₂ZrF₆ at 46° C., then washed with demineralised water. The support thus obtained was characterised by a surface roughness Rₐ of 0.72 μm (measured with interferometer NT3300) and had an anodic weight of 3.2 g/m².

Substrate 4.

A 0.3 mm thick aluminium foil was degreased by dipping an aqueous solution containing 10 g/l NaOH at 47.5° C. for 20 seconds and rinsed for 20 seconds with a mixture of HCl and demineralised water. The foil was then electrochemically grained during 20 seconds using an alternating current in an aqueous solution containing 9 g/l HCl, 15 g/l acetic acid and 1.5 g/l Al³⁺ ions at a temperature of 29° C. and a charge density of about 1250 C/dm². The foil was then sprayed with water for 20 seconds. Afterwards, the aluminium foil was desmutted by etching with an aqueous solution containing 100 g/l of phosphoric acid at 45° C. for 20 seconds and rinsed with demineralised water. The foil was subsequently subjected to anodic oxidation in an aqueous solution containing 145 g/l of sulphuric acid at a temperature of 45° C. and a charge density of about 200 C/dm², then washed with demineralised water. Afterwards, the foil was post-treated by dipping for 20 seconds in a solution containing 4.5 g/l K₂ZrF₆ at 46° C., then washed with demineralised water. The support thus obtained was characterised by a surface roughness Rₐ of 0.94 μm (measured with interferometer NT3300) and had an anodic weight of 3.2 g/m².

Substrate 5.

A 0.3 mm thick aluminium foil was first mechanically grained and then degreased by spraying with an aqueous solution containing 34 g/l NaOH at 75° C. for 6 seconds and rinsed with demineralised water for 3.6 seconds. The foil was then electrochemically grained during 8 seconds using an alternating current in an aqueous solution containing 12.5 g/l HCl, 12 g/l SO₄²⁻ ions and 5 g/l Al³⁺ ions at a temperature of 37° C. and a charge density of 900 C/dm². Afterwards, the aluminium foil was desmutted by etching with an aqueous solution containing 145 g/l of sulphuric acid at 80° C. for 5 seconds and rinsed with demineralised water for 4 seconds. The foil was subsequently subjected to anodic oxidation during 10 seconds in an aqueous solution containing 145 g/l of sulphuric acid at a temperature of 57° C. and a current density of 30 A/dm², then washed with demineralised water for 7 seconds and post-treated for 6 seconds (dipping) with a solution containing 2.2 g/l PVPA at 70° C., rinsed with demineralised water for 3.5 seconds and dried at 120° C. for 7 seconds. The support thus obtained was characterised by a surface roughness Rₐ of 0.75 μm (measured with interferometer NT3300) and had an anodic weight of 3.6 g/m².

Substrate 6.

A 0.3 mm thick aluminium foil was first mechanically grained and then degreased by spraying with an aqueous solution containing 34 g/l NaOH at 75° C. for 6 seconds and rinsed with demineralised water for 3.6 seconds. The foil was then electrochemically grained during 8 seconds using an alternating current in an aqueous solution containing 12.5 g/l HCl, 12 g/l SO₄²⁻ ions and 5 g/l Al³⁺ ions at a temperature of 37° C. and a current density of 800 C/dm². Afterwards, the aluminium foil was desmutted by etching with an aqueous solution containing 145 g/l of sulphuric acid at 80° C. for 5 seconds and rinsed with demineralised water for 4 seconds. The foil was subsequently subjected to anodic oxidation during 10 seconds in an aqueous solution containing 145 g/l of sulphuric acid at a temperature of 57° C. and a current density of 30 A/dm², then washed with demineralised water for 7 seconds and post-treated for 6 seconds (dipping) with a solution containing 2.2 g/l PVPA at 70° C., rinsed with demineralised water for 3.5 seconds and dried at 120° C. for 7 seconds. The support thus obtained was characterised by a surface roughness Rₐ of 0.63 μm (measured with interferometer NT3300) and had an anodic weight of 3.7 g/m².

Substrate 7.

A 0.3 mm thick aluminium foil was first mechanically grained and then degreased by spraying with an aqueous solution containing 34 g/l NaOH at 75° C. for 6 seconds and rinsed with demineralised water for 3.6 seconds. The foil was then electrochemically grained during 8 seconds using an alternating current in an aqueous solution containing 12.5 g/l HCl, 12 g/l SO₄²⁻ ions and 5 g/l Al³⁺ ions at a temperature of 37° C. and a charge density of 960 C/dm². Afterwards, the aluminium foil was desmutted by etching with an aqueous solution containing 145 g/l of sulphuric acid at 80° C. for 5 seconds and rinsed with demineralised water for 4 seconds. The foil was subsequently subjected to anodic oxidation during 10 seconds in an aqueous solution containing 145 g/l of sulphuric acid at a temperature of 57° C. and a current density of 30 A/dm², then washed with demineralised water for 7 seconds and post-treated for 6 seconds (dipping) with a solution containing 2.2 g/l PVPA at 70° C., rinsed with demineralised water for 3.5 seconds and dried at 120° C. for 7 seconds. The support thus obtained was characterised by a surface roughness Rₐ of 0.82 μm (measured with interferometer NT3300) and had an anodic weight of 3.7 g/m².

Substrate 8.

A 0.3 mm thick aluminium foil was degreased by spraying with an aqueous solution containing 34 g/l NaOH at 75° C. for 6 seconds and rinsed with demineralised water for 3.6 seconds. The foil was then electrochemically grained during 8 seconds using an alternating current in an aqueous solution containing 15.4 g/l HNO₃ and 5 g/l Al³⁺ ions at a temperature of 40° C. and a charge density of 1120 C/dm². Afterwards, the aluminium foil was desmutted by etching with an aqueous solution containing 145 g/l of sulphuric acid at 80° C. for 5 seconds and rinsed with demineralised water for 4 seconds. The foil was subsequently subjected to anodic oxidation during 10 seconds in an aqueous solution containing 145 g/l of sulphuric acid at a temperature of 57° C. and a current density of about 20 A/dm², then washed with demineralised water for 7 seconds and post-treated for 6 seconds (dipping) with a solution containing 2.2 g/l PVPA at 70° C., rinsed with demineralised water for 3.5 seconds and dried at 120° C. for 7 seconds. The support thus obtained was characterised by a surface roughness Rₐ of 0.58 μm (measured with interferometer NT3300) and had an anodic weight of 2.1 g/m².

Substrate 9.

A 0.3 mm thick aluminium foil was degreased by spraying with an aqueous solution containing 34 g/l NaOH at 70° C. for 6 seconds and rinsed with demineralised water for 3.6 seconds. The foil was then electrochemically grained during 8 seconds using an alternating current in an aqueous solution containing 15 g/l HCl, 15 g/l SO₄²⁻ ions and 5 g/l Al³⁺ ions at a temperature of 37° C. and a charge density of 800 C/dm². Afterwards, the aluminium foil was desmutted by etching with an aqueous solution containing 145 g/l of sulphuric acid at 80° C. for 5 seconds and rinsed with demineralised water for 4 seconds. The foil was subsequently subjected to anodic oxidation during 10 seconds in an aqueous solution containing 145 g/l of sulphuric acid at a temperature of 57° C. and a current density of 33 A/dm², then washed with demineralised water for 7 seconds and post-treated for 4 seconds (by spray) with a solution containing 2.2 g/l PVPA at 70° C., rinsed with demineralised water for 3.5 seconds and dried at 120° C. for 7 seconds. The support thus obtained was characterised by a surface roughness Rₐ of 0.37 μm (measured with interferometer NT1100) and had an anodic weight of 3.9 g/m².

Substrate 10.

A 0.3 mm thick aluminium foil was degreased by spraying with an aqueous solution containing 34 g/l NaOH at 70° C. for 6 seconds and rinsed with demineralised water for 3.6 seconds. The foil was then electrochemically grained during 8 seconds using an alternating current in an aqueous solution containing 15 g/l HCl, 15 g/l SO₄²⁻ ions and 5 g/l Al³⁺ ions at a temperature of 37° C. and a current density of about 80 A/dm². Afterwards, the aluminium foil was desmutted by etching with an aqueous solution containing 145 g/l of sulphuric acid at 80° C. for 5 seconds and rinsed with demineralised water for 4 seconds. The foil was subsequently subjected to anodic oxidation during 10 seconds in an aqueous solution containing 145 g/l of sulphuric acid at a temperature of 57° C. and a charge density of 650 C/dm², then washed with demineralised water for 7 seconds and post-treated for 4 seconds (by spray) with a solution containing 2.2 g/l PVPA at 70° C., rinsed with demineralised water for 3.5 seconds and dried at 120° C. for 7 seconds. The support thus obtained was characterised by a surface roughness Rₐ of 0.31 μm (measured with interferometer NT1100) and had an anodic weight of 4 g/m².

Substrate 11.

A 0.3 mm thick aluminium foil was degreased by spraying with an aqueous solution containing 34 g/l NaOH at 70° C. for 6 seconds and rinsed with demineralised water for 3.6 seconds. The foil was then electrochemically grained during 8 seconds using an alternating current in an aqueous solution containing 15 g/l HCl, 15 g/l SO₄²⁻ ions and 5 g/l Al³⁺ ions at a temperature of 37° C. and a charge density of 700 C/dm². Afterwards, the aluminium foil was desmutted by etching an aqueous solution containing 145 g/l of sulphuric acid at 80° C. for 5 seconds and rinsed with demineralised water for 4 seconds. The foil was subsequently subjected to anodic oxidation during 10 seconds in an aqueous solution containing 145 g/l of sulphuric acid at a temperature of 57° C. and a current density of 33 A/dm², then washed with demineralised water for 7 seconds and post-treated for 4 seconds (by spray) with a solution containing 2.2 g/l PVPA at 70° C., rinsed with demineralised water for 3.5 seconds and dried at 120° C. for 7 seconds. The support thus obtained was characterised by a surface roughness Rₐ of 0.34 μm (measured with interferometer NT1100) and had an anodic weight of 4.1 g/m².

Substrate 12.

A 0.3 mm thick aluminium foil was degreased by dipping an aqueous solution containing 15 g/l NaOH at 50° C. for 20 seconds and rinsed for 20 seconds with a mixture of HCl and demineralised water. The foil was then electrochemically grained during 20 seconds using an alternating current in an aqueous solution containing 7.5 g/l HCl, 10 g/l acetic acid and 1.5 g/l Al³⁺ ions at a temperature of 32° C. and a charge density of about 700 C/dm². Afterwards, the aluminium foil was desmutted by etching with an aqueous solution containing 410 g/l of phosphoric acid at 50° C. for 20 seconds and rinsed with demineralised water. The foil was subsequently subjected to anodic oxidation in an aqueous solution containing 250 g/l of sulphuric acid at a temperature of 25° C. and a charge density of about 240 C/dm², then washed with demineralised water. Afterwards, the foil was post-treated by dipping for 20 seconds in a solution containing 4.5 g/l PVPA at 70° C., then washed with demineralised water. The support thus obtained was characterised by a surface roughness Rₐ of 0.5 μm (measured with interferometer NT3300) and had an anodic weight of 3 g/m².

Substrate 13.

A 0.3 mm thick aluminium foil was degreased by dipping an aqueous solution containing 15 g/l NaOH at 50° C. for 20 seconds and rinsed for 20 seconds with a mixture of HCl and demineralised water. The foil was then electrochemically grained during 20 seconds using an alternating current in an aqueous solution containing 6.5 g/l HCl, 16 g/l acetic acid and 1.5 g/l Al³⁺ ions at a temperature of 32° C. and a charge density of about 700 C/dm². Afterwards, the aluminium foil was desmutted by etching with an aqueous solution containing 410 g/l of phosphoric acid at 50° C. for 20 seconds and rinsed with demineralised water. The foil was subsequently subjected to anodic oxidation in an aqueous solution containing 250 g/l of sulphuric acid at a temperature of 25° C. and a charge density of 240 C/dm², then washed with demineralised water. Afterwards, the foil was post-treated by dipping for 20 seconds in a solution containing 4.5 g/l PVPA at 70° C., then washed with demineralised water. The support thus obtained was characterised by a surface roughness Rₐ of 0.44 μm (measured with interferometer NT3300) and had an anodic weight of 3 g/m².

Substrate 14.

A 0.3 mm thick aluminium foil was degreased by spraying with an aqueous solution containing 34 g/l NaOH at 70° C. for 6 seconds and rinsed with demineralised water for 3.6 seconds. The foil was then electrochemically grained during 8 seconds using an alternating current in an aqueous solution containing 15 g/l HCl, 15 g/l SO₄²⁻ ions and 5 g/l Al³⁺ ions at a temperature of 37° C. and a charge density of 900 C/dm². Afterwards, the aluminium foil was desmutted by etching with an aqueous solution containing 145 g/l of sulphuric acid at 80° C. for 5 seconds and rinsed with demineralised water for 4 seconds. The foil was subsequently subjected to anodic oxidation during 10 seconds in an aqueous solution containing 145 g/l of sulphuric acid at a temperature of 57° C. and a current density of 33 A/dm², then washed with demineralised water for 7 seconds and post-treated for 4 seconds (by spray) with a solution containing 2.2 g/l PVPA at 70° C., rinsed with demineralised water for 3.5 seconds and dried at 120° C. for 7 seconds. The support thus obtained was characterised by a surface roughness Rₐ of 0.44 μm (measured with interferometer NT3300) and had an anodic weight of 4.0 g/m².

Substrate 15.

A 0.3 mm thick aluminium foil was degreased by spraying with an aqueous solution containing 34 g/l NaOH at 70° C. for 6 seconds and rinsed with demineralised water for 3.6 seconds. The foil was then electrochemically grained during 8 seconds using an alternating current in an aqueous solution containing 15 g/l HCl, 15 g/l SO₄²⁻ ions and 5 g/l Al³⁺ ions at a temperature of 37° C. and a charge density of 800 C/dm². Afterwards, the aluminium foil was desmutted by etching with an aqueous solution containing 145 g/l of sulphuric acid at 80° C. for 5 seconds and rinsed with demineralised water for 4 seconds. The foil was subsequently subjected to anodic oxidation during 10 seconds in an aqueous solution containing 145 g/l of sulphuric acid at a temperature of 57° C. and a current density of 33 A/dm², then washed with demineralised water for 7 seconds and post-treated for 4 seconds (by spray) with a solution containing 2.2 g/l PVPA at 70° C., rinsed with demineralised water for 3.5 seconds and dried at 120° C. for 7 seconds. The support thus obtained was characterised by a surface roughness Rₐ of 0.34 μm (measured with interferometer NT1100) and had an anodic weight of 4.1 g/m².

Substrate 16.

A 0.3 mm thick aluminium foil was degreased by spraying with an aqueous solution containing 34 g/l NaOH at 70° C. for 6 seconds and rinsed with demineralised water for 3.6 seconds. The foil was then electrochemically grained during 8 seconds using an alternating current in an aqueous solution containing 15 g/l HCl, 15 g/l SO₄²⁻ ions and 5 g/l Al³⁺ ions at a temperature of 37° C. and a charge density of 620 C/dm². Afterwards, the aluminium foil was desmutted by etching with an aqueous solution containing 145 g/l of sulphuric acid at 80° C. for 5 seconds and rinsed with demineralised water for 4 seconds. The foil was subsequently subjected to anodic oxidation during 10 seconds in an aqueous solution containing 145 g/l of sulphuric acid at a temperature of 57° C. and a current density of 33 A/dm², then washed with demineralised water for 7 seconds and post-treated for 4 seconds (by spray) with a solution containing 2.2 g/l PVPA at 70° C., rinsed with demineralised water for 3.5 seconds and dried at 120° C. for 7 seconds. The support thus obtained was characterised by a surface roughness Rₐ of 0.31 μm (measured with interferometer NT1100) and had an anodic weight of 4 g/m².

Substrate 17.

A 0.3 mm thick aluminium foil was degreased by spraying with an aqueous solution containing 34 g/l NaOH at 70° C. for 6 seconds and rinsed with demineralised water for 3.6 seconds. The foil was then electrochemically grained during 8 seconds using an alternating current in an aqueous solution containing 15 g/l HCl, 15 g/l SO₄²⁻ ions and 5 g/l Al³⁺ ions at a temperature of 37° C. and a charge density of 900 C/dm². Afterwards, the aluminium foil was desmutted by etching with an aqueous solution containing 145 g/l of sulphuric acid at 80° C. for 5 seconds and rinsed with demineralised water for 4 seconds. The foil was subsequently subjected to anodic oxidation during 10 seconds in an aqueous solution containing 145 g/l of sulphuric acid at a temperature of 57° C. and a current density of 33 A/dm², then washed with demineralised water for 7 seconds and post-treated for 4 seconds (by spray) with a solution containing 2.2 g/l PVPA at 70° C., rinsed with demineralised water for 3.5 seconds and dried at 120° C. for 7 seconds. The support thus obtained was characterised by a surface roughness Rₐ of 0.42 μm (measured with interferometer NT1100) and had an anodic weight of 4.1 g/m².

Substrate 18.

A 0.3 mm thick aluminium foil was degreased by spraying with an aqueous solution containing 34 g/l NaOH at 70° C. for 6 seconds and rinsed with demineralised water for 3.6 seconds. The foil was then electrochemically grained during 8 seconds using an alternating current in an aqueous solution containing 15 g/l HCl, 15 g/l SO₄²⁻ ions and 5 g/l Al³⁺ ions at a temperature of 37° C. and a charge density of 900 C/dm². Afterwards, the aluminium foil was desmutted by etching with an aqueous solution containing 145 g/l of sulphuric acid at 80° C. for 5 seconds and rinsed with demineralised water for 4 seconds. The foil was subsequently subjected to anodic oxidation during 10 seconds in an aqueous solution containing 145 g/l of sulphuric acid at a temperature of 57° C. and a current density of 33 A/dm², then washed with demineralised water for 7 seconds and post-treated for 4 seconds (by spray) with a solution containing 2.2 g/l PVPA at 70° C., rinsed with demineralised water for 3.5 seconds and dried at 120° C. for 7 seconds. The support thus obtained was characterised by a surface roughness Rₐ of 0.37 μm (measured with interferometer NT1100) and had an anodic weight of 3.9 g/m².

Substrate 19.

A 0.3 mm thick aluminium foil was degreased by spraying with an aqueous solution containing 34 g/l NaOH at 70° C. for 6 seconds and rinsed with demineralised water for 3.6 seconds. The foil was then electrochemically grained during 8 seconds using an alternating current in an aqueous solution containing 15 g/l HCl, 15 g/l SO₄²⁻ ions and 5 g/l Al³⁺ ions at a temperature of 37° C. and a charge density of 750 C/dm². Afterwards, the aluminium foil was desmutted by etching with an aqueous solution containing 145 g/l of sulphuric acid at 80° C. for 5 seconds and rinsed with demineralised water for 4 seconds. The foil was subsequently subjected to anodic oxidation during 10 seconds in an aqueous solution containing 145 g/l of sulphuric acid at a temperature of 57° C. and a current density of 33 A/dm², then washed with demineralised water for 7 seconds and post-treated for 4 seconds (by spray) with a solution containing 2.2 g/l PVPA at 70° C., rinsed with demineralised water for 3.5 seconds and dried at 120° C. for 7 seconds. The support thus obtained was characterised by a surface roughness Rₐ of 0.36 μm (measured with interferometer NT1100) and had an anodic weight of 3.9 g/m².

Substrate 20.

A 0.3 mm thick aluminium foil was degreased by spraying with an aqueous solution containing 34 g/l NaOH at 70° C. for 6 seconds and rinsed with demineralised water for 3.6 seconds. The foil was then electrochemically grained during 8 seconds using an alternating current in an aqueous solution containing 15 g/l HCl, 15 g/l SO₄²⁻ ions and 5 g/l Al³⁺ ions at a temperature of 37° C. and a charge density of 680 C/dm². Afterwards, the aluminium foil was desmutted by etching with an aqueous solution containing 145 g/l of sulphuric acid at 80° C. for 5 seconds and rinsed with demineralised water for 4 seconds. The foil was subsequently subjected to anodic oxidation during 10 seconds in an aqueous solution containing 145 g/l of sulphuric acid at a temperature of 57° C. and a current density of 33 A/dm², then washed with demineralised water for 7 seconds and post-treated for 4 seconds (by spray) with a solution containing 2.2 g/l PVPA at 70° C., rinsed with demineralised water for 3.5 seconds and dried at 120° C. for 7 seconds. The support thus obtained was characterised by a surface roughness Rₐ of 0.34 μm (measured with interferometer NT1100) and had an anodic weight of 4.0 g/m².

### 2) Determination of Pit Depth, Pit Area and Pit Volume of the Lithographic Substrates 1-20

Based on the information obtained from image analysis of interferometer images at 10× magnification of the substrates, a computer program, for example MatLAb code, calculates the mean values of the area, depth and volume of the pits present on the surface of the aluminum support. The results are summarized in Tables 4, 5 and 6.

### 3) Preparation of the Printing Plate Precursors PPP-1 to PPP-20

Preparation of Binder-01.

In a 250 ml reactor, 162 mmol of Monomer-01, 21.3 g (132 mmol) benzyl acrylamide, 0.43 g (6 mmol) acrylic acid and 1039 gamma-butyrolactone were added and the mixture was heated to 140° C., while stirring at 200 rpm. A constant flow of nitrogen was put over the reactor. After dissolution of all the components, the reactor was cooled to 100° C. 0.35 ml Trigonox DC50, commercially available from AKZO NOBEL, was added followed by the addition of 1.39 ml Trigonox 141, commercially available from AKZO NOBEL, in 3.43 ml butyrolactone. The polymerization was started and the reactor was heated to 140° C. over 2 hours while dosing 1.75 ml Trigonox DC50. The mixture was stirred at 400 rpm and the polymerization was allowed to continue for 2 hours at 140° C. The reaction mixture was cooled to 120° C. and the stirrer speed was enhanced to 500 rpm. 85.7 ml 1-methoxy-2-propanol was added and the reaction mixture was allowed to cool down to room temperature.

Binder-01 was analyzed with ¹H-NMR-spectroscopy and size exclusion chromatography, using dimethyl acetamide/0.21% LiCl as eluent on a 3× mixed-B column and relative to polystyrene standards.

| | Mₙ | M_{w} | PD |
|---|---|---|---|
| Binder-01 | 23500 | 67000 | 2.84 |

The reaction mixture was cooled to 40° C. and the resulting 25 weight % polymer solution was collected in a drum.

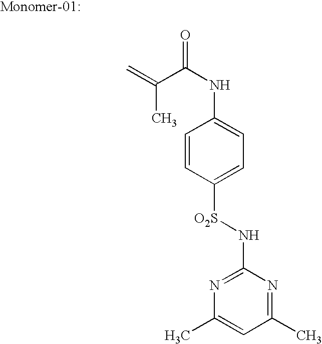

The printing plate precursors PPP-1 to PPP-20 were, prepared by first applying a layer with a composition as defined in Table 2 onto the above described lithographic supports 1-20. The solvent used to apply this layer is a mixture of 60% tetrahydrofuran (THF)/40% Dowanol PM (1-methoxy-2-propanol from Dow Chemical Company). The coating solution was applied at a wet coating thickness of 20 μm and then dried at 135° C.

TABLE 2
Composition of the second layer.

| | % wt dry | |
|---|---|---|
| INGREDIENTS | weight | mg/m² |
| Binder-01 (1) | 98.29 | 978.0 |
| Basonyl blue 640 (2) | 1.51 | 15.0 |
| TEGO 410 (3) | 0.20 | 2.0 |

(1) Binder-01 is a 25 wt. % solution in 50% wt butyrolactam/50% wt Dowanol PM (1-methoxy-2-propanol from Dow Chemical Company) of the copolymer comprising a sulphonamide substituted methacrylate monomer as described above;
(2) Basonyl Blue 640 is a quaternized triaryl methane dye, commercially available from BASF;
(3) Tego 410 is Tegoglide 410, a copolymer of polysiloxane and polyalkylene oxide, commercially available from Tego Chemie Service GmbH.

Onto the dried layer, another layer with a composition as defined in Table 3 was coated at a wet thickness of 16 μm and dried at 135° C. The solvent used to apply the coating is a mixture of 50% methylethyl ketone (MEK)/50% Dowanol PM (1-methoxy-2-propanol from Dow Chemical Company). The dry coating weight of this layer was 0.81 g/m².

TABLE 3
Composition of the first layer.

| | % wt dry | |
|---|---|---|
| INGREDIENTS | weight | mg/m² |
| Alnovol SP452 (1) | 82.64 | 666.5 |
| 3,4,5-trimethoxy cinnamic acid | 11.16 | 90.0 |
| SOO94 IR-1 (2) | 4.22 | 34.0 |
| Basonyl blue 640 (3) | 1.24 | 10.0 |
| Tegoglide 265 (4) | 0.17 | 1.4 |
| Tegowet 410 (4) | 0.57 | 4.6 |

(1) 40.5 weight % solution of novolac in Dowanol PM, commercially available from Clariant;
(2) IR absorbing cyanine dye, commercially available from FEW CHEMICALS, chemical structure is equal to IR-1 (see above);
(3) quaternised triaryl methane dye, commercially available from BASF;
(4) copolymer of polysiloxane and polyalkylene oxide, commercially available from Tego Chemie Service GmbH.

### 4) Image-Wise Exposure and Developing

The printing plate precursors PPP-1 to PPP-20 were exposed with a Creo Trendsetter TH551 20W (plate-setter, trademark from Creo, Burnaby, Canada), operating at 150 rpm and at an energy density 30% below the right exposure energy density; thus at 30% underexposure. The right exposure energy density is the minimum energy density at which a 50% dot area (200 lpi) is obtained after processing of a precursor imaged with a 50% screen and is measured using a ^{CC}Dot³ commercially available from Centurfax Ltd.

The imagewise underexposed plate precursors were processed by in an Agfa Autolith TP85 processor (trademark from Agfa) by dipping them in a tank in steps of 10 seconds with a maximum of 120 seconds at 22° C., and using the Agfa Energy developer, commercially available by Agfa-Gevaert.

### 5) Evaluation of Blue Spots

The colored spots occurring at the image-areas after exposure and developing were measured and quantified using an image technique i.e. ImageXpert Full Motion System (commercially available form ImageXpert Inc., Nashua, USA) equipped with a 3 CCD color camera and a Rodenstock Apo-Rodagon-D 2× lens. The relative area coverage by the blue spots is obtained as a percentage and the results are given in Tables 4, 5 and 6.

The mean pit depth, mean pit volume and mean pit area in relation to the amount of blue spots are summarized in Tables 4, 5 and 6.

TABLE 4
mean pit depth values and blue spots.

| | Mean depth | Standard | Blue |
|---|---|---|---|
| Substrate | μm | deviation | spots |
| 1 | 3.65 | 0.48 | 0.24 |
| 2 | 2.74 | 0.60 | 1.5 |
| 3 | 2.78 | 0.64 | 0.74 |
| 4 | 3.38 | 0.56 | 0.43 |
| 5 | 3.02 | 0.76 | 0.91 |
| 6 | 2.57 | 0.61 | 0.56 |
| 7 | 3.22 | 0.75 | 0.34 |
| 8 | 2.32 | 0.34 | 0.58 |
| 9 | 1.35 | 0.31 | 0.14 |
| 10 | 1.01 | 0.17 | 0.07 |
| 11 | 1.24 | 0.22 | 0.03 |
| 12 | 1.81 | 0.37 | 0.14 |
| 13 | 1.56 | 0.31 | 0.03 |
| 14 | 1.58 | 0.35 | 0.15 |
| 15 | 1.33 | 0.26 | 0.03 |
| 16 | 0.99 | 0.16 | 0.05 |
| 17 | 1.54 | 0.28 | 0.13 |
| 18 | 1.49 | 0.24 | 0.03 |
| 19 | 1.38 | 0.25 | 0.08 |
| 20 | 1.16 | 0.22 | 0.11 |

The results of Table 4 show that the mean pit depth correlates well with the amount of blue spots: a mean pit dept ≦2.2 μm results in an amount of blue spots ≦0.2. Above 2.2 μm, the amount of blue spots is significantly higher.

TABLE 5
mean pit area values and blue spots.

| | Mean area | Standard | Blue |
|---|---|---|---|
| Substrate | μm² | deviation | spots |
| 1 | 33.51 | 54.40 | 0.24 |
| 2 | 56.72 | 85.13 | 1.5 |
| 3 | 58.07 | 98.20 | 0.74 |
| 4 | 55.31 | 79.86 | 0.43 |
| 5 | 69.36 | 115.23 | 0.91 |
| 6 | 42.40 | 64.24 | 0.56 |
| 7 | 76.57 | 121.83 | 0.34 |
| 8 | 26.08 | 40.52 | 0.58 |
| 9 | 15.64 | 20.4 | 0.14 |
| 10 | 10.59 | 15.21 | 0.07 |
| 11 | 11.97 | 15.37 | 0.03 |
| 12 | 20.52 | 27.95 | 0.14 |
| 13 | 18.60 | 24.62 | 0.03 |
| 14 | 18.38 | 28.37 | 0.15 |
| 15 | 15.08 | 19.43 | 0.03 |
| 16 | 9.99 | 15.13 | 0.05 |
| 17 | 14.92 | 20.93 | 0.13 |
| 18 | 12.13 | 16.91 | 0.03 |
| 19 | 13.7 | 18.41 | 0.08 |
| 20 | 12.58 | 16.64 | 0.11 |

The results of Table 5 show that the mean pit area correlates well with the amount of blue spots: a mean pit area ≦25 μm² results in an amount of blue spots ≦0.2. Above 25 μm², the amount of blue spots is significantly higher.

TABLE 6
mean pit volume values and blue spots.

| | Mean volume | Standard | Blue |
|---|---|---|---|
| Substrate | μm³ | deviation | spots |
| 1 | 120.68 | 204.68 | 0.24 |
| 2 | 149.11 | 237.92 | 1.5 |
| 3 | 156.03 | 283.74 | 0.74 |
| 4 | 178.50 | 269.87 | 0.43 |
| 5 | 203.71 | 364.92 | 0.91 |
| 6 | 106.61 | 177.04 | 0.56 |
| 7 | 238.71 | 410.28 | 0.34 |
| 8 | 59.52 | 98.50 | 0.58 |
| 9 | 20.74 | 0.14 | 0.14 |
| 10 | 10.34 | 0.07 | 0.07 |
| 11 | 14.35 | 0.03 | 0.03 |
| 12 | 36.02 | 0.14 | 0.14 |
| 13 | 27.87 | 0.03 | 0.03 |
| 14 | 28.89 | 0.15 | 0.15 |
| 15 | 19.18 | 0.03 | 0.03 |
| 16 | 9.54 | 0.05 | 0.05 |
| 17 | 22.46 | 0.13 | 0.13 |
| 18 | 17.78 | 0.03 | 0.03 |
| 19 | 18.16 | 0.08 | 0.08 |
| 20 | 14.05 | 0.11 | 0.11 |

The results of Table 6 show that the mean pit area correlates well with the amount of blue spots: a mean pit area ≦55 μm³ results in an amount of blue spots ≦0.2. Above 55 μm³, the amount of blue spots is significantly higher.

1-10. (canceled)

11. A positive-working lithographic printing plate precursor comprising on a grained and anodized aluminum support having a hydrophilic surface a coating comprising:
(i) an infrared absorbing agent and at least one colorant;
(ii) a first layer comprising a heat-sensitive oleophilic resin; and
(iii) a second layer between said first layer and said hydrophilic support, wherein said second layer comprises a polymer comprising at least one monomeric unit that comprises at least one sulfonamide group,
wherein the surface of said grained and anodized aluminum support has a mean pit depth equal to or less than 2.2 μm.

12. The printing plate precursor according to claim 11, wherein the mean pit depth is equal to or less than 2.0 μm.

13. The printing plate precursor according to claim 11, wherein the mean pit area is equal to or less than 25 μm².

14. The printing plate precursor according to claim 11, wherein the mean pit volume is equal to or less than 55 μm³.

15. The printing plate precursor according to claim 11, wherein the monomeric unit that comprises at least one sulfonamide group is represented by the following formula (I): 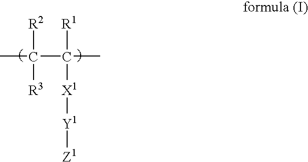
wherein:
R¹ represents hydrogen or a hydrocarbon group having up to 12 carbon atoms;
R² and R³ independently represent hydrogen or a hydrocarbon group;
X¹ represents a single bond or divalent linking group;
Y¹ is a bivalent sulphonamide group represented by —NR^{j}—SO₂— or —SO₂—NR^{k}— wherein R^{j} and R^{k} each independently represent hydrogen, an optionally substituted alkyl, alkanoyl, alkenyl, alkynyl, cycloalkyl, heterocyclic, aryl, heteroaryl, aralkyl or heteroaralkyl group or a group of the formula —C(═N)—NH—R², wherein R² represents hydrogen or an optionally substituted alkyl or aryl group; and
Z¹ represents a terminal group or a bi-, tri- or quadrivalent linking group wherein the remaining 1 to 3 bonds of Z¹ are linked to Y¹.

16. The printing plate precursor according to claim 15, wherein the coating further comprises a barrier layer above said first and second layer, said barrier layer comprising a development inhibitor selected from the group consisting of:
a water-repellent polymer or copolymer;
a bifunctional compound comprising a polar group and a hydrophobic group; and
a bifunctional block-copolymer comprising a polar block and a hydrophobic block.

17. The printing plate precursor according to claim 16, wherein the bifunctional compound comprising a polar group and a hydrophobic group is a surfactant and is present in an amount ranging from 10 to 100 mg/m² relative to the coating weight

18. The printing plate precursor according to claim 16, wherein the bifunctional block-copolymer comprises a poly- or oligo(alkylene oxide) block and a hydrophobic block.

19. The printing plate precursor according to claim 18, wherein the bifunctional block-copolymer comprises one or more of a long-chain hydrocarbon group, a poly- or oligosiloxane or a perfluorinated hydrocarbon group.

20. The printing plate precursor according to claim 18, wherein the amount of the bifunctional block-copolymer is between 0.5 and 25 mg/m² relative to the coating weight.

21. The printing plate precursor according to claim 11, wherein the coating further comprises a barrier layer above said first and second layer, said barrier layer comprising a development inhibitor selected from the group consisting of:
a water-repellent polymer or copolymer;
a bifunctional compound comprising a polar group and a hydrophobic group; and
a bifunctional block-copolymer comprising a polar block and a hydrophobic block.

22. The printing plate precursor according to claim 21, wherein the bifunctional compound comprising a polar group and a hydrophobic group is a surfactant and is present in an amount ranging from 10 to 100 mg/m² relative to the coating weight.

23. The printing plate precursor according to claim 21, wherein the bifunctional block-copolymer comprises a poly- or oligo(alkylene oxide) block and a hydrophobic block.

24. The printing plate precursor according to claim 23, wherein the bifunctional block-copolymer comprises one or more of a long-chain hydrocarbon group, a poly- or oligosiloxane or a perfluorinated hydrocarbon group.

25. The printing plate precursor according to claim 23, wherein the amount of the bifunctional block-copolymer is between 0.5 and 25 mg/m² relative to the coating weight.

26. The printing plate precursor according to claim 13, wherein the monomeric unit that comprises at least one sulfonamide group is represented by the following formula (I): 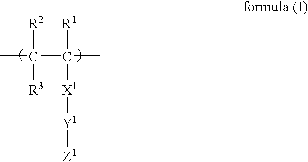
wherein:
R¹ represents hydrogen or a hydrocarbon group having up to 12 carbon atoms;
R² and R³ independently represent hydrogen or a hydrocarbon group;
X¹ represents a single bond or divalent linking group;
Y¹ is a bivalent sulphonamide group represented by —NR^{j}—SO₂— or —SO₂—NR^{k}— wherein R^{j} and R^{k} each independently represent hydrogen, an optionally substituted alkyl, alkanoyl, alkenyl, alkynyl, cycloalkyl, heterocyclic, aryl, heteroaryl, aralkyl or heteroaralkyl group or a group of the formula —C(═N)—NH—R², wherein R² represents hydrogen or an optionally substituted alkyl or aryl group; and
Z¹ represents a terminal group or a bi-, tri- or quadrivalent linking group wherein the remaining 1 to 3 bonds of Z¹ are linked to Y¹.

27. The printing plate precursor according to claim 13, wherein the coating further comprises a barrier layer above said first and second layer, the barrier layer comprising a development inhibitor selected from the group consisting of:
a water-repellent polymer or copolymer;
a bifunctional compound comprising a polar group and a hydrophobic group; and
a bifunctional block-copolymer comprising a polar block and a hydrophobic block.

28. A method for making a positive-working heat-sensitive lithographic printing plate comprising the steps of:
(i) providing a printing plate precursor according to claim 11;
(ii) image-wise exposing said precursor to heat and/or IR-light; and
(iii) developing said exposed precursor with an aqueous alkaline developing solution, wherein the coating at the exposed areas is removed while essentially not affecting the coating at the non-exposed areas.

29. The method according to claim 28, wherein the mean pit area is equal to or less than 25 μm².

30. The method according to claim 28, wherein the monomeric unit that comprises at least one sulfonamide group is represented by the following formula (I): 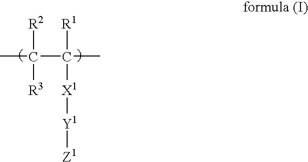
wherein:
R¹ represents hydrogen or a hydrocarbon group having up to 12 carbon atoms;
R² and R³ independently represent hydrogen or a hydrocarbon group;
X¹ represents a single bond or divalent linking group;
Y¹ is a bivalent sulphonamide group represented by —NR^{j}—SO₂— or —SO₂—NR^{k}— wherein R^{j} and R^{k} each independently represent hydrogen, an optionally substituted alkyl, alkanoyl, alkenyl, alkynyl, cycloalkyl, heterocyclic, aryl, heteroaryl, aralkyl or heteroaralkyl group or a group of the formula —C(═N)—NH—R², wherein R² represents hydrogen or an optionally substituted alkyl or aryl group; and
Z¹ represents a terminal group or a bi-, tri- or quadrivalent linking group wherein the remaining 1 to 3 bonds of Z¹ are linked to Y¹.

31. The method according to claim 28, wherein the coating further comprises a barrier layer above said first and second layer, the barrier layer comprising a development inhibitor selected from the group consisting of:
a water-repellent polymer or copolymer;
a bifunctional compound comprising a polar group and a hydrophobic group; and
a bifunctional block-copolymer comprising a polar block and a hydrophobic block.

32. The method according to claim 31, wherein the bifunctional compound comprising a polar group and a hydrophobic group is a surfactant and is present in an amount ranging from 10 to 100 mg/m² relative to the coating weight.

33. The method according to claim 31, wherein the bifunctional block-copolymer comprises a poly- or oligo(alkylene oxide) block and a hydrophobic block.

34. The method according to claim 33, wherein the bifunctional block-copolymer comprises one or more of a long-chain hydrocarbon group, a poly- or oligosiloxane or a perfluorinated hydrocarbon group.

35. The method according to claim 33, wherein the amount of the bifunctional block-copolymer is between 0.5 and 25 mg/m² relative to the coating weight.

36. The method according to claim 30, wherein the coating further comprises a barrier layer above said first and second layer, the barrier layer comprising a development inhibitor selected from the group consisting of:
a water-repellent polymer or copolymer;
a bifunctional compound comprising a polar group and a hydrophobic group; and
a bifunctional block-copolymer comprising a polar block and a hydrophobic block.

37. The method according to claim 36, wherein the bifunctional compound comprising a polar group and a hydrophobic group is a surfactant and is present in an amount ranging from 10 to 100 mg/m² relative to the coating weight.

38. The method according to claim 36, wherein the bifunctional block-copolymer comprises a poly- or oligo(alkylene oxide) block and a hydrophobic block.

39. The method according to claim 38, wherein the bifunctional compound comprising a poly-oliog(alkylene oxide) block and a hydrophobic group is a surfactant and is present in an amount ranging from 10 to 100 mg/m² relative to the coating weight.

40. The method according to claim 38, wherein the amount of the bifunctional block-copolymer is between 0.5 and 25 mg/m² relative to the coating weight.
